(19) United States
(12) Patent Application Publication
(10) Pub. No.: US 2016/0079120 A1
(43) Pub. Date: Mar. 17, 2016

(54) SEMICONDUCTOR DEVICE AND METHOD OF MANUFACTURING THE SAME

(71) Applicant: KABUSHIKI KAISHA TOSHIBA, Tokyo (JP)

(72) Inventors: Shingo MASUKO, Kanazawa Ishikawa (JP); Yoshiharu TAKADA, Nonoichi Ishikawa (JP); Yasuhiro ISOBE, Kanazawa Ishikawa (JP)

(21) Appl. No.: 14/637,277

(22) Filed: Mar. 3, 2015

(30) Foreign Application Priority Data
Sep. 12, 2014 (JP) 2014-186131

(51) Int. Cl. H01L 21/78; H01L 21/308; H01L 21/3065; H01L 29/06; H01L 29/20; H01L 21/306

(52) U.S. Cl. CPC H01L 21/78; H01L 29/2003; H01L 21/30625; H01L 21/3065; H01L 29/0657; H01L 21/308

(57) ABSTRACT

A semiconductor device includes a semiconductor substrate that has a first surface and a second surface opposite to the first surface, and has a groove or trench extending from the first surface toward the second surface, a bottom of the groove being situated between the first surface and the second surface, and a gallium nitride-containing layer on the first surface of the semiconductor substrate having a trench tapering inwardly along a direction toward the first surface of the semiconductor substrate and connected to the groove.

### CROSS-REFERENCE TO RELATED APPLICATION

This application is based upon and claims the benefit of priority from Japanese Patent Application No. 2014-186131, filed Sep. 12, 2014, the entire contents of which are incorporated herein by reference.

### FIELD

Embodiments described herein relate generally to a semiconductor device and a method of manufacturing the same.

### BACKGROUND

A semiconductor device such as a gallium nitride-based HEMT (High Electron Mobility Transistor) has a layered structure formed by laminating a plurality of gallium nitride-containing layers on a substrate. Here, as the substrate, an inexpensive silicon substrate may sometimes be used in order to reduce the cost or enlarge the diameter of the layered structure.

However, when a gallium nitride-containing layer is formed on a silicon substrate, local stress is applied to the silicon substrate. Singulation by dicing of the silicon substrate and the gallium nitride-containing layer in such a situation may cause a defect such as a crack and a chip in the silicon substrate.

### DESCRIPTION OF THE DRAWINGS

FIG. 1A is a schematic plane view illustrating an essential part of a layered structure according to a first embodiment, and FIG. 1B is a schematic cross-sectional view at a position along the A-A′ line of FIG. 1A.

FIGS. 2A to 2C are schematic cross-sectional views illustrating a manufacturing process of a layered structure according to the first embodiment.

FIGS. 3A to 3C are schematic cross-sectional views illustrating a manufacturing process of a layered structure according to the first embodiment.

FIGS. 4A to 4D are schematic cross-sectional views illustrating a manufacturing process of a layered structure according to a reference example.

FIG. 5 is a schematic cross-sectional view illustrating an essential part of a semiconductor device according to a second embodiment.

### DETAILED DESCRIPTION

Embodiments provide a semiconductor device and a method of manufacturing the same capable of suppressing defects therein.

In general, according to one embodiment, a semiconductor device includes: a semiconductor substrate that has a first surface and a second surface opposed to the first surface, and has a groove formed in the first surface extending toward the second surface, a bottom of the groove being situated between the first surface and the second surface, and a gallium nitride-containing layer on the first surface of the semiconductor substrate, having a trench tapering inwardly along a direction toward the semiconductor substrate and connected to the groove.

Embodiments will be described below with reference to the accompanying drawings. In the following description, the same numbers are assigned to the same portion of the device shown in the Figs., and the description of the portions described in previous Figs. is omitted as appropriate.

### First Embodiment

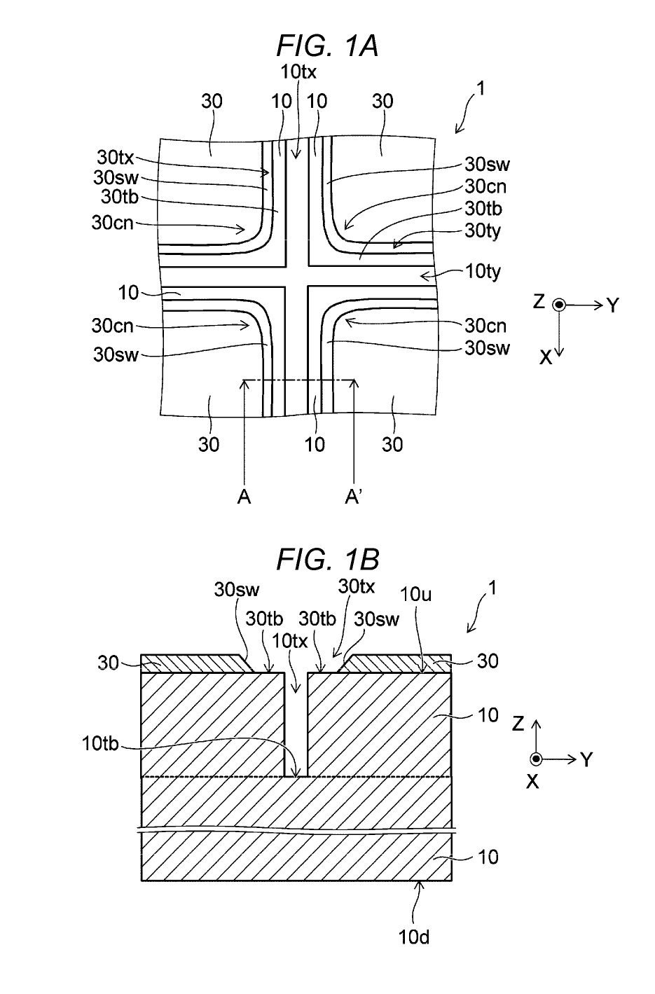

FIG. 1A is a schematic plane view illustrating an essential part of a layered structure according to a first embodiment, and FIG. 1B is a schematic cross-sectional view at a position along the A-A′ line of FIG. 1A.

A semiconductor device (hereinafter referred to as, for example, a layered structure 1) according to a first embodiment includes a silicon substrate 10 and a gallium nitride-containing layer 30 provided on the silicon substrate 10.

A dicing groove (hereinafter referred to as, for example, a trench 10tx) is provided extending inwardly of the silicon substrate 10. The trench 10tx extends along the substrate 10 in a first direction (hereinafter referred to as, for example, an X direction). Further, a second dicing groove (hereinafter referred to as, for example, a trench 10ty) is provided extending inwardly of the silicon substrate 10. The trench 10ty extends along the substrate 10 in a second direction (hereinafter referred to as, for example, a Y direction). Here, the X direction and the Y direction intersect.

The width of the trench 10tx is substantially the same as the width of the trench 10ty. Here, “width” refers to the dimension of the trench in the directions perpendicular to the direction that the trench extends along the substrate 10 and inwardly of the substrate 10, for example in direction Y of FIG. 1B for trench 10tx. The depth of the trench 10tx is substantially the same as the depth of the trench 10ty. The trench 10tx and the trench 10ty extend inwardly of the substrate 10 from a first surface of the silicon substrate 10 (hereinafter referred to as, for example, an upper surface 10u) toward a second surface opposite to the upper surface (hereinafter referred to as, for example, a lower surface 10d). In addition, the bottom 10tb of the trench 10tx, 10ty is situated between the upper surface 10u and the lower surface 10d of the silicon substrate 10.

A second trench (hereinafter referred to as, for example, a trench 30tx) is provided in the gallium nitride-containing layer 30. The trench 30tx is provided over the upper end of the trench 10tx. The trench 30tx is thus connected to the trench 10tx. The trench 30tx extends along the gallium nitride containing layer 30 in the X direction. The trench 30tx tapers toward the upper surface 10u of the silicon substrate 10, such that the trench 30tx narrows in the depth direction thereof through the gallium nitride containing layer 30. In other words, the side 30sw of the trench 30tx has a forward tapered shape so that the trench widens in the Z direction away from the substrate 10. Further, the width of the trench 30tx is larger than the width of the trench 10tx. A portion of the silicon substrate 10 is exposed at the bottom 30tb of the trench 30tx to either side of trench 10tx.

In addition, although the cross-section of the trench 30tx and the like in the gallium nitride-containing layer 30 is shown in FIG. 1B, as illustrated in FIG. 1A, a trench 30ty is also provided in the gallium nitride-containing layer 30. The trench 30ty is provided over the upper side of the trench 10ty. The trench 30ty extends along the substrate 10 in the Y direction. The trench 30ty tapers inwardly as it approaches the upper surface 10u of the silicon substrate 10. In other words, the side 30sw of the trench 30ty has a forward tapered shape. Further, the width of the trench 30ty is larger than the width of the trench 10ty. The upper surface 10u of the silicon substrate 10 is exposed at the bottom 30tb of the trench 30ty on either side of trench 10ty.

The width of the trench 30tx is substantially the same as the width of the trench 30ty. The depth of the trench 30tx is substantially the same as the depth of the trench 30ty. Further, when viewing the layered structure 1 from the Z direction, a corner 30cn of the gallium nitride-containing layer 30 where the trench 30tx and the trench 30ty intersect has a curvature and thus has a round shape forming a portion of a circle or ellipse the and continues the taper of both trenches 30tx and 30ty around this rounded corner, thus forming a continuous chamfered side wall of the trenches 30tx and 30ty including a chamfered corner 30cn.

Note that, by way of example, the thickness of the silicon substrate 10 is 1 mm. By way of example, the depth of the trench 10tx, 10ty is greater than or equal to 200 μm. By way of example, the thickness of the gallium nitride-containing layer 30 is 10 μm. In addition, when the layered structure 1 is applied to the device, part or all of the silicon substrate 10 below the bottom 10tb of the trench 10tx, 10ty may sometimes be removed after the trenches 10, 30 are formed. The structure after the removal is also included in the embodiment.

Further, in the embodiment, the trench 10tx and trench 10ty may be collectively referred to as a trench 10t. In addition, in the embodiment, the trench 30tx and trench 30ty may be collectively referred to as a trench 30t.

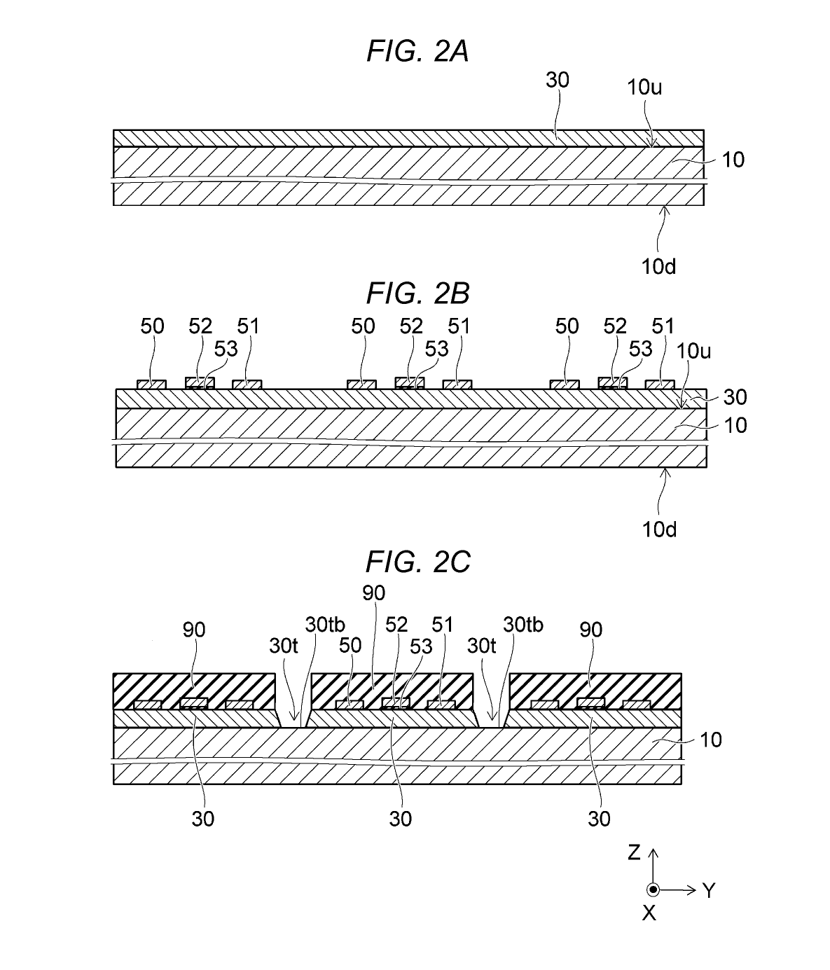

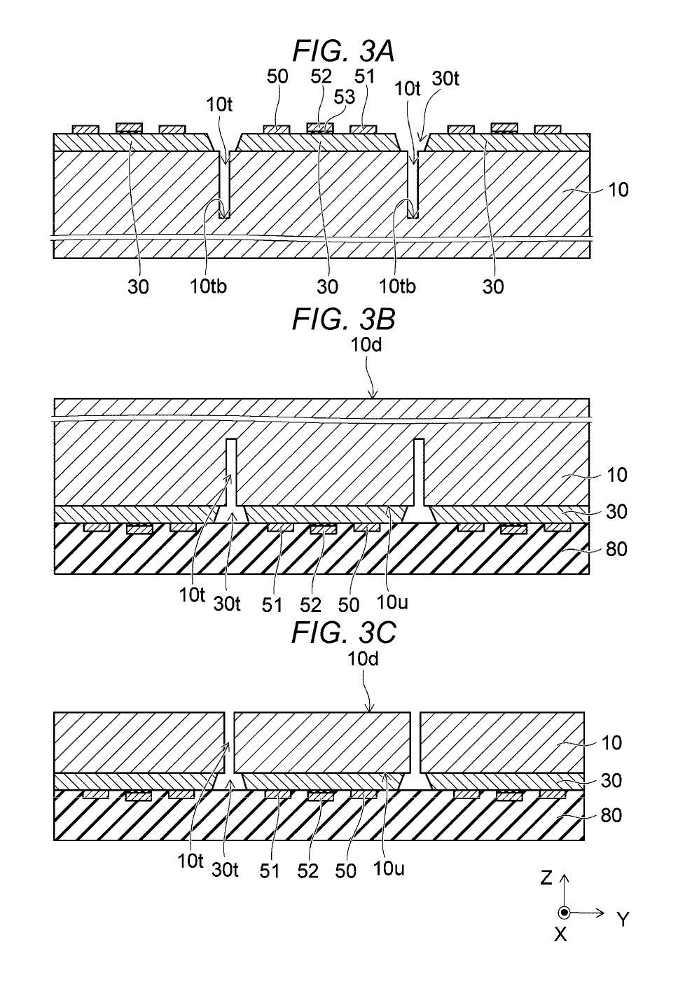

FIGS. 2A to 3C are schematic cross-sectional views illustrating a manufacturing process of a layered structure according to the first embodiment.

For example, as illustrated in FIG. 2A, epitaxial growth of the gallium nitride-containing layer 30 is performed on the upper surface 10u side of the silicon substrate 10. Here, the silicon substrate 10 has the upper surface 10u, and the lower surface 10d opposite to the upper surface 10u. By way of example, the silicon substrate 10 is a silicon wafer having an outer diameter of 6 to 12 inches. By way of example, the thickness of the silicon substrate 10 is 1 mm. By way of example, the thickness of the gallium nitride-containing layer 30 is 10 μm. The layered structure of the gallium nitride-containing layer 30 will be described later herein.

Next, as illustrated in FIG. 2B, first electrodes (hereinafter referred to as, for example, a source electrode 50), second electrodes (hereinafter referred to as, for example, a drain electrode 51) and third electrodes (hereinafter referred to as, for example, a gate electrode 52) are selectively formed on the gallium nitride-containing layer 30. A gate insulating film 53 such as a this silicon oxide layer is formed on the gallium nitride-containing layer 30 before forming the gate electrode 52. A source electrode 50, a gate electrode 51, and an intermediate gate electrode 52 formed over a gate insulation layer 53 are provided for each individual semiconductor device which will be singulated (separated) from the semiconductor substrate 10.

Next, as illustrated in FIG. 2C, a patterned mask layer 90 which covers the source electrode 50, the drain electrode 51 the gate electrode 52, and the gallium nitride-containing layer 30 is formed. The part of the gallium nitride-containing layer 30 exposed by the pattern openings in the mask layer 90 is on a dicing line along which individual devices (or die) are to be singulated from the substrate 10. Subsequently, the gallium nitride-containing layer 30 exposed within the openings in the mask layer 90 is subjected to reactive ion etching (RIE).

Thus, the gallium nitride-containing layer 30 is selectively etched, and a plurality of trenches 30t are formed in the gallium nitride-containing layer 30. Note that, in this stage, the gallium nitride-containing layer 30 exposed in the openings in the mask layer 90 may not be completely removed. That is, an extremely thin gallium nitride-containing layer 30 may remain on the bottom 30tb of the trench 30t. Further, the way of selectively removing the gallium nitride-containing layer 30 is not limited to RIE, but may include wet or dry etching.

Note that, although the configuration in which the trench 30t extending in the X direction is formed is illustrated in FIG. 2C, the trench 30t extending in the Y direction is also formed (see FIG. 1A) by these steps. Further, when viewing the gallium nitride-containing layer 30 from the Z direction after RIE, the corner 30cn of the gallium nitride-containing layer 30 where the trench 30t extending in the X direction and the trench 30t extending in the Y direction intersect has a rounded chamfered shape (see FIG. 1A).

Next, as illustrated in FIG. 3A to 3C, after removing the mask layer 90, the dicing processes are performed on the silicon substrate 10 below the plurality of trenches 30t. For example, a dicing blade (not illustrated) having a narrower width than that of the trench 30t is used to cut into the silicon substrate 10 exposed in the trench 30t. Here, the width of the dicing blade is narrower than that of the trench 30t. Therefore, a dicing groove (trench 10t) having narrower width than that of the trench 30t is formed in the silicon substrate 10 as shown in FIG. 3A. The trench 10t has a substantially straight shape.

Further, in this stage, the DBG (Dicing Before Grinding) process in which cutting of the dicing line extends only to the middle region of the silicon substrate 10 such that the trench 10t does not penetrate the silicon substrate 10 is performed. In other words, the bottom 10tb of the trench 10t is situated between the upper surface 10u and the lower surface 10d of the silicon substrate 10. Here, the depth of the trench 10t is greater than or equal to the thickness of the final silicon substrate 10 after the back side surface 10d is ground away to expose the bottoms 10tb of the trenches 10tb. For example, the depth of the trench 10t extending inwardly of upper surface 10u side of the substrate 10 is greater than or equal to 200 μm.

Note that, although the configuration in which the trench 10t extending in the X direction is formed is illustrated in FIG. 3A, the trench 10t extending in the Y direction is also formed (see FIG. 1A) by this process.

Next, as illustrated in FIG. 3B, grinding support tape 80 is pasted on the gallium nitride-containing layer 30 located on the upper surface 10u of the silicon substrate 10.

Next, as illustrated in FIG. 3C, the lower surface 10d of the silicon substrate 10 is ground away to expose the plurality of trenches 10t at the lower surface 10d, after grinding, of the silicon substrate 10. Thus, the silicon substrate 10 and the gallium nitride-containing layer 30 are singulated into a plurality of device chips or die. Note that the thickness of the silicon substrate 10 after singulation is, for example, 200 μm. Thereafter, the grinding support tape 80 is peeled off of the gallium nitride-containing layer 30.

Before the effects of the first embodiment are described, the layered structure of the reference example will be described.

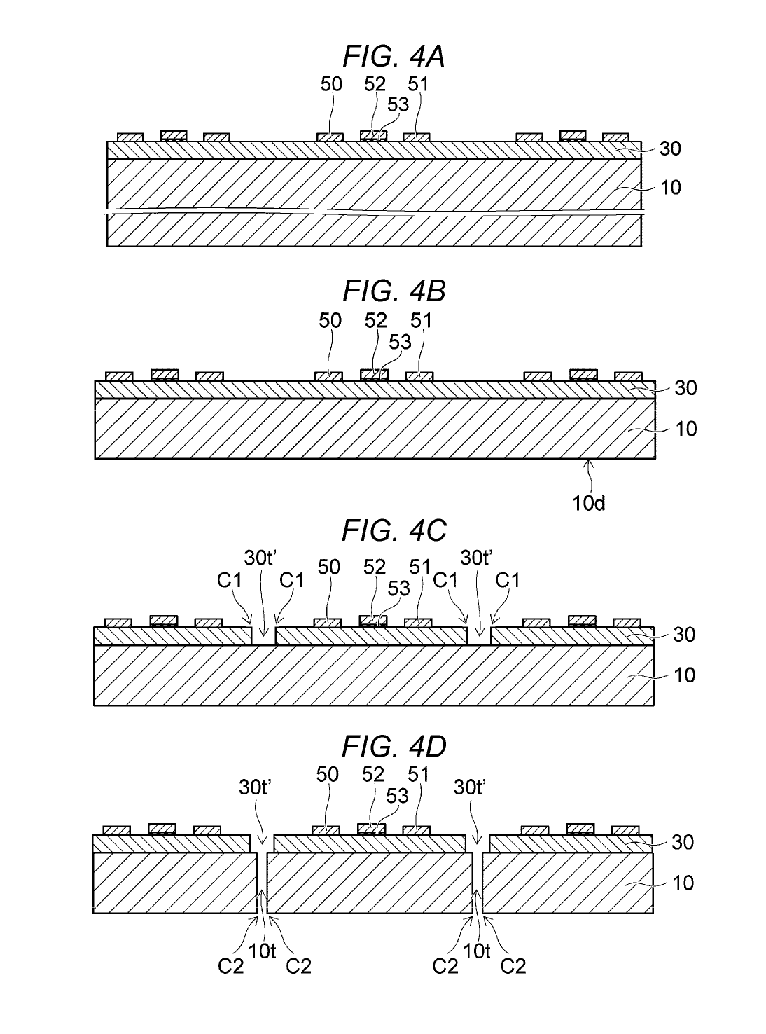

FIGS. 4A to 4D are schematic cross-sectional views illustrating a manufacturing process of a layered structure according to a reference example.

For example, as illustrated in FIG. 4A, epitaxial growth of the gallium nitride-containing layer 30 is performed on the silicon substrate 10. The source electrode 50, the drain electrode 51, and the gate electrode 52 over the gate insulating film 53, are selectively provided on the gallium nitride-containing layer 30. By way of example, the thickness of the silicon substrate 10 is 1 mm. By way of example, the thickness of the gallium nitride-containing layer 30 is 10 μm.

Next, as illustrated in FIG. 4B, the lower surface 10d of the silicon substrate 10 is ground away to the final thickness of the singulated device chip. The thickness of the silicon substrate 10 after grinding is, for example, 200 μm.

Next, as illustrated in FIG. 4C, a dicing blade (not illustrated) is used to perform a cutting process on the gallium nitride-containing layer 30. Thus, a trench 30t′ having a substantially straight shape is formed through or substantially through the gallium nitride-containing layer 30.

Next, as illustrated in FIG. 4D, a dicing blade (not illustrated) having a narrower width than that of the trench 30t is used to cut through and thus singulate the silicon substrate 10 below the trench 30t′ into individual device chips. Thus, a dicing groove (trench 10t) having narrower width than that of the trench 30t is formed in the silicon substrate 10. In the reference example, full-cut dicing in which the trench 10t penetrates the silicon substrate 10 is performed.

However, the hardness of the gallium nitride-containing layer 30 is higher than that of the silicon substrate 10. Therefore, it takes a longer time to dice the gallium nitride-containing layer 30, inevitably. Further, dicing the gallium nitride-containing layer 30 causes the dicing blade to significantly wear out, which increases the frequency of replacement of the dicing blade.

In addition, in the layered structure obtained by forming the gallium nitride-containing layer 30 on the silicon substrate 10, stress is applied to each of the gallium nitride-containing layer 30 and the silicon substrate 10.

Therefore, when the dicing blade is directly applied to the gallium nitride-containing layer 30 to dice the gallium nitride-containing layer 30, a defect such as a crack or a chip may occur in a position in the gallium nitride-containing layer 30 indicated by the arrow C1 (FIG. 4C), for example. Therefore, in the reference example, the area where a defect is likely to occur is unused in the resulting device chip, resulting unused surface area on the device chip and limits the reduction in the chip size.

On the other hand, since stress is also applied to the silicon substrate 10, when full-cut dicing is performed on the silicon substrate 10, a defect such as a crack and a chip may also occur in a position in the silicon substrate 10 indicated by the arrow C2 (FIG. 4D). Thus, the transverse strength of the chip using the silicon substrate 10 and the gallium nitride-containing layer 30 according to the reference example is low.

In contrast, in the first embodiment, the gallium nitride-containing layer 30 is separated by RIE. Thus, in the first embodiment, the step of dicing the gallium nitride-containing layer 30 is not required. That is to say, in the first embodiment, the time of dicing the gallium nitride-containing layer 30, and a dicing blade for separating the gallium nitride-containing layer 30 are not required. Thus, it is possible to reduce the cost of manufacturing.

Even if the extremely thin gallium nitride-containing layer 30 remains on the bottom 30tb of the trench 30t, the gallium nitride-containing layer 30 to be cut is significantly reduced as compared to the reference example.

Further, in the first embodiment, the gallium nitride-containing layer 30 is separated by RIE, not by a dicing blade brought into contact with the gallium nitride-containing layer 30. As a result, a defect such as a crack and a chip is less likely to occur in the gallium nitride-containing layer 30. Therefore, in the first embodiment, there is no unused area shown in the reference example, thus it is possible to reduce the chip size.

In addition, in the first embodiment, it is not required to fully cut the silicon substrate 10. In the first embodiment, the singulation of the silicon substrate 10 is performed not by dicing individual device chips by cutting through the substrate 10, but by a grinding method after dicing which is stopped once the bottoms of the trenches inside the silicon substrate 10 are exposed. Therefore, a defect such as a crack and a chip is less likely to occur in the silicon substrate 10 after singulation. Thus, in the first embodiment, the transverse strength of the chip using the silicon substrate and the gallium nitride-containing layer 30 after singulation is higher compared to the reference example.

### Second Embodiment

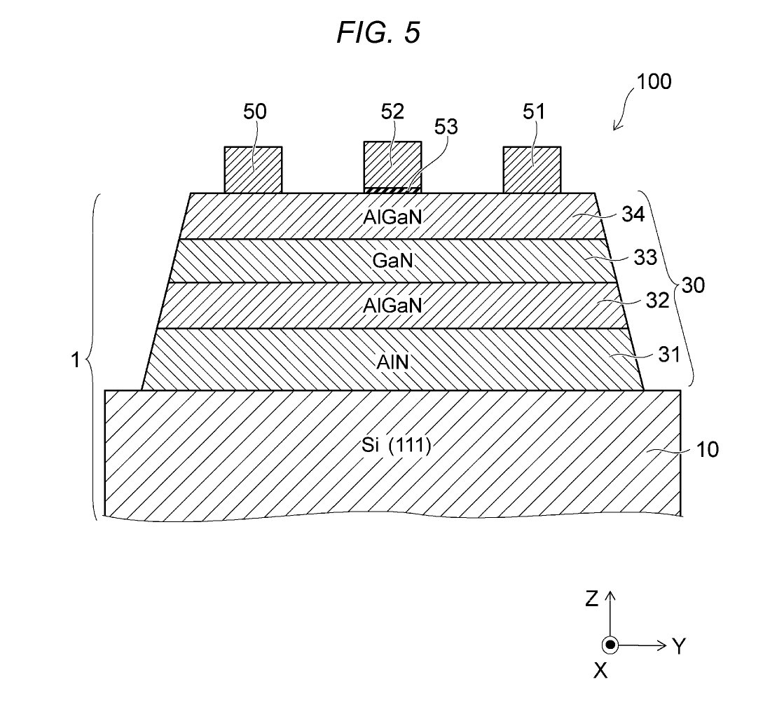

FIG. 5 is a schematic cross-sectional view illustrating an essential part of a semiconductor device according to a second embodiment.

The semiconductor device 100 according to the second embodiment includes the layered structure 1, the source electrode 50 provided on the layered structure 1, the drain electrode 51 parallel to the source electrode 50 and the gate electrode 52 provided between the source electrode 50 and the drain electrode 51. The gate insulating film 53 is provided between the gate electrode 52 and the layered structure 1. The semiconductor device 100 is a HEMT.

The gallium nitride-containing layer 30 includes an aluminum nitride-containing layer 31, an aluminum gallium nitride-containing layer 32, a gallium nitride-containing layer 33 and an aluminum gallium nitride-containing layer 34.

The source electrode 50 and the drain electrode 51 are in ohmic contact with the aluminum gallium nitride-containing layer 34. The gate insulating film 53 includes any one of silicon nitride film (Si₃N₄), silicon oxide film (SᵢO₂) and aluminum oxide (Al₂O₃).

Each of the aluminum nitride-containing layer 31 and the aluminum gallium nitride-containing layer 32 function as a buffer layer of the HEMT for transitioning the mismatch between the crystal structure of the monocrystalline silicon substrate 10 to the crystal structure of the GaN layer. The gallium nitride-containing layer 33 functions as a carrier transit layer of the HEMT. The aluminum gallium nitride-containing layer 34 functions as a barrier layer of the HEMT. The aluminum gallium nitride-containing layer 34 is a non-doped or n-type Al_{X}Ga₁₋ₓN (0<X≦1) layer. An electron high density is generated near the interface between the gallium nitride-containing layer 33 and the aluminum gallium nitride-containing layer 34 in the gallium nitride-containing layer 33. The semiconductor device 100 formed with this structure is also included in the embodiment.

Note that “nitride semiconductor” herein includes, as a whole, semiconductors of all compositions comprising the chemical formula BₓIn_{y}Al_{z}Ga_{1-x-y-z}N (0≦x≦1, 0≦y≦1, 0≦z≦1, x+y+z≦1), in which the composition ratios x, y and z are varied within their respective ranges. Furthermore, “nitride semiconductor” includes semiconductors further containing in the chemical formula an element from the Group V other than N (nitrogen), those further containing a variety of elements to be added to control various physical properties such as conductivity type, and, those further containing a variety of elements whereof the inclusion has no intended purpose.

In the embodiment described above, “on” in an expression that “a portion A is provided on a portion B” is used to mean a case where the portion A does not come into contact with the portion B and the portion A is provided above the portion B in addition to a case where the portion A comes into contact with the portion B and the portion A is provided on the portion B. Furthermore, “the portion A is provided on the portion B” may be applied to a case where the portion A and the portion Bare reversed and the portion A is positioned below the portion B, or a case where the portion A and the portion B are horizontally provided in the same line with each other. This is because the structure of the semiconductor device is not changed between before and after the rotation thereof even if the semiconductor device according to the embodiment is rotated.

Hitherto, the embodiments are described with reference to the specific examples. However, the embodiments are not limited to the specific examples. That is, one in which those skilled in the art apply appropriate design changes to those specific examples is included in the range of the embodiments as long as it includes the characteristics of the embodiments. Each element included in the specific examples and, an arrangement, a material, a condition, a shape, a size thereof, and the like are not limited to those which are illustrated above and can be appropriately changed.

Furthermore, each of the elements included in each embodiment can be combined as long as it is technically possible and the combination is included in the range of the embodiments as long as each of the elements includes the characteristics of the embodiments. In addition, in a category of the spirit of the embodiments, those skilled in the art can derive various modified examples and corrected examples, and the modified examples and the corrected examples are understood to be also included in the range of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate having a first surface and a second surface opposed to the first surface and a groove formed inwardly of the first surface toward the second surface, the bottom of the groove being situated between the first surface and the second surface; and
a gallium nitride-containing layer on the first surface of the silicon substrate, having a trench that tapers inwardly along a direction toward the semiconductor substrate and is connected to the groove.

2. The semiconductor device according to claim 1, wherein the width of the trench is wider than the width of the groove.

3. The semiconductor device according to claim 1, wherein the silicon substrate is exposed at the bottom of the first trench on at least one side of the groove.

4. The semiconductor device according to claim 1, wherein the trench includes
a first trench extending along the first surface in a first direction and a second trench extending along the first surface in a second direction intersecting the first direction, and
a corner of the gallium nitride-containing layer located where the first trench and the second trench intersect is curved.

5. The semiconductor device according to claim 4, wherein the wall of the second trench is tapered inwardly of the second trench; and
the curved corner at the intersection of the first and second trenches is tapered inwardly.

6. The semiconductor device according to claim 4, wherein the curved corner is rounded in the shape of a partial circle or partial ellipse.

7. The semiconductor device according to claim 1, wherein the depth of the groove inwardly of the substrate is at least 200 μm.

8. The semiconductor device of claim 7, further comprising another groove extending inwardly of the substrate, wherein the grooves have the same depth.

9. The semiconductor device of claim 8, further comprising a semiconductor device region on either side of each of the grooves.

10. A method of manufacturing a semiconductor device comprising:
etching a gallium nitride-containing layer on a first surface of a semiconductor substrate which has a first surface and an opposed second surface to form a plurality of grooves comprising a first bottom in the gallium nitride-containing layer;
cutting into the semiconductor substrate through the first bottom to form a second bottom, the second bottom being located between the first surface and the second surface; and
polishing the second surface of the semiconductor substrate to expose the plurality of grooves through the second surface side of the semiconductor substrate, so that the semiconductor substrate and the gallium nitride-containing layer are separated into a plurality of chips.

11. The method of claim 10, wherein
the gallium nitride-containing layer is etched by reactive ion etching.

12. The method of claim 11, further comprising:
forming a patterned etch mask over the gallium nitride containing layer; and
forming the plurality of grooves by reactive ion etching the gallium nitride containing layer exposed in the patterned openings in the etch mask.

13. The method of claim 11, wherein the plurality of grooves include at least two grooves extending in a first direction and at least two grooves extending in a second direction which intersect the grooves formed in the first direction.

14. The method of claim 13, wherein, at the intersection of grooves, a rounded corner is formed.

15. The method of claim 13, wherein the grooves have opposed sidewalls tapering inwardly along a direction toward the semiconductor substrate.

16. The method of claim 15, wherein at least two of the grooves intersect thereby forming a rounded corner at the intersection thereof.

17. The method of claim 16, wherein the rounded corner has a tapered wall forming an extension of the tapered wall of the grooves around the rounded corner.

18. The method of claim 10, wherein at least a portion of a groove extends through the gallium nitride containing layer and exposes a portion of the semiconductor substrate therein.

19. The method of claim 10, wherein the semiconductor substrate comprises a silicon substrate.

20. A gallium nitride containing semiconductor device, comprising:
a semiconductor substrate having a plurality of intersecting sidewalls and a first hardness;
a gallium nitride layer on the semiconductor substrate, having a plurality of intersecting sidewalls and a second hardness greater than the first hardness, wherein the sidewalls of the gallium nitride containing layer are tapered outwardly in the depth direction of the gallium nitride containing layer; and
a rounded corner, having an outward taper in the depth direction of the gallium nitride containing layer, at the locations where the sidewalls of the gallium nitride containing layer intersect.
